(19) United States
(12) Patent Application Publication
(10) Pub. No.: US 2017/0159881 A1
(43) Pub. Date: Jun. 8, 2017

(54) HEAD MOUNTED DISPLAY HOUSING

(71) Applicant: Oculus VR, LLC, Menlo Park, CA (US)

(72) Inventor: Matt Lee Thomas, Yorba Linda, CA (US)

(21) Appl. No.: 14/961,832

(22) Filed: Dec. 7, 2015

(51) Int. Cl. F16M 13/04; H05K 5/00; H05K 5/02

(52) U.S. Cl. CPC F16M 13/04; H05K 5/0204; H05K 5/0086

(57) ABSTRACT

Technology is provided for a head mounted display housing for use with a portable display device. The head mounted display housing includes a housing body including a facial interface portion and a frame portion. The facial interface portion is configured to confront the face of a user. A strap assembly is coupled to the housing body and retains the facial interface portion against a user's face. The frame portion has surrounding channels configured to contain the portable display device and an opening to receive the portable display device into the channels. A door mount is positioned adjacent the opening, and a door is coupled to the door mount. The door moves between an open position to allow access to the surrounding channels and a closed position to retain the portable display device in the frame portion. The door includes a pair of tabs configured to latch against the frame portion.

### TECHNICAL FIELD

This patent application is directed to head mounted displays and, more specifically, to head mounted display housings.

### BACKGROUND

Traditional head mounted displays use a portable display device, such as a mobile phone, which is snapped onto the housing. This method of mounting a portable display device to the housing can leave the portable display device vulnerable to being dislodged from the housing during use. Accordingly, there is a need for an improved head mounted display housing.

### BRIEF DESCRIPTION OF THE DRAWINGS

Embodiments of the head mounted display housing introduced herein may be better understood by referring to the following Detailed Description in conjunction with the accompanying drawings, in which like reference numerals indicate identical or functionally similar elements:

FIG. 1 is a perspective view of a head mounted display housing according to a representative embodiment.

FIG. 2 is a perspective view of the housing body shown in FIG. 1.

FIG. 3 is a perspective view of the housing body shown in FIGS. 1 and 2 as viewed from the front.

FIG. 4 is a partial perspective view of the housing body shown in FIGS. 1-3.

The headings provided herein are for convenience only and do not necessarily affect the scope or meaning of the claimed embodiments. Further, the drawings have not necessarily been drawn to scale. For example, the dimensions of some of the elements in the figures may be expanded or reduced to help improve the understanding of the embodiments. Moreover, while the disclosed technology is amenable to various modifications and alternative forms, specific embodiments have been shown by way of example in the drawings and are described in detail below. The intention, however, is not to limit the embodiments described. On the contrary, the embodiments are intended to cover all modifications, equivalents, and alternatives falling within the scope of the embodiments as defined by the appended claims.

### DETAILED DESCRIPTION

### Overview

A head mounted display for use with a portable display device is disclosed. The head mounted display includes a housing with a housing body including a facial interface portion and a frame portion. The facial interface portion is configured to confront the face of a user. A strap assembly is coupled to the housing body and retains the facial interface portion against a user's face. In some embodiments, the frame portion can have surrounding channels configured to contain the portable display device and an opening to receive the portable display device into the surrounding channels. In some embodiments, a door mount is positioned adjacent the opening, and a door is coupled to the door mount. The door moves between an open position to allow access to the surrounding channels and a closed position to retain the portable display device in the frame portion. In some embodiments, the door includes a pair of tabs configured to latch against the frame portion. The surrounding channels and the door of the frame portion provide a secure mount for the portable display device.

### General Description

Various examples of the devices introduced above will now be described in further detail. The following description provides specific details for a thorough understanding and enabling description of these examples. One skilled in the relevant art will understand, however, that the techniques discussed herein may be practiced without many of these details. Likewise, one skilled in the relevant art will also understand that the technology can include many other features not described in detail herein. Additionally, some well-known structures or functions may not be shown or described in detail below so as to avoid unnecessarily obscuring the relevant description.

The terminology used below is to be interpreted in its broadest reasonable manner, even though it is being used in conjunction with a detailed description of some specific examples of the embodiments. Indeed, some terms may even be emphasized below; however, any terminology intended to be interpreted in any restricted manner will be overtly and specifically defined as such in this section.

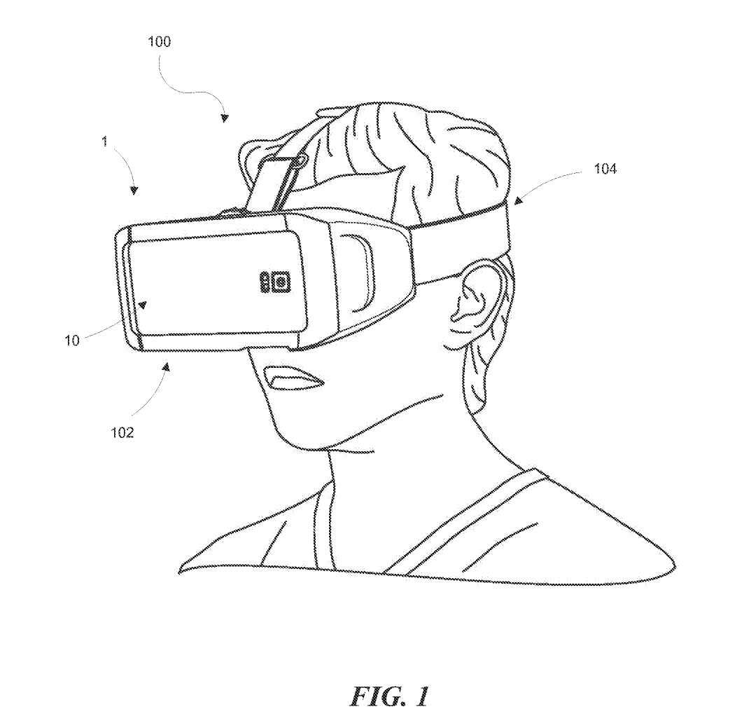

FIG. 1 shows a head mounted display 1 with a head mounted display housing 100 according to a representative embodiment. The head mounted display housing 100 includes a housing body 102 and a strap assembly 104 configured to hold the head mounted display housing 100 on a user's head during use. The housing body 102 is configured to releasably retain a portable display device 10, such as a mobile phone or other display device. The housing body of the illustrated embodiment has a contoured, aesthetically attractive shape. In at least one embodiment, the housing body can have an ornamentally contoured shape as shown in Applicants U.S. Design Patent Application No. 29/547,765, (Attorney Docket No. 60406-8284.US01) titled “HEAD MOUNTED DISPLAY WITH PHONE RECEPTACLE,” filed concurrently herewith, and which is incorporated herein in its entirety by reference thereto.

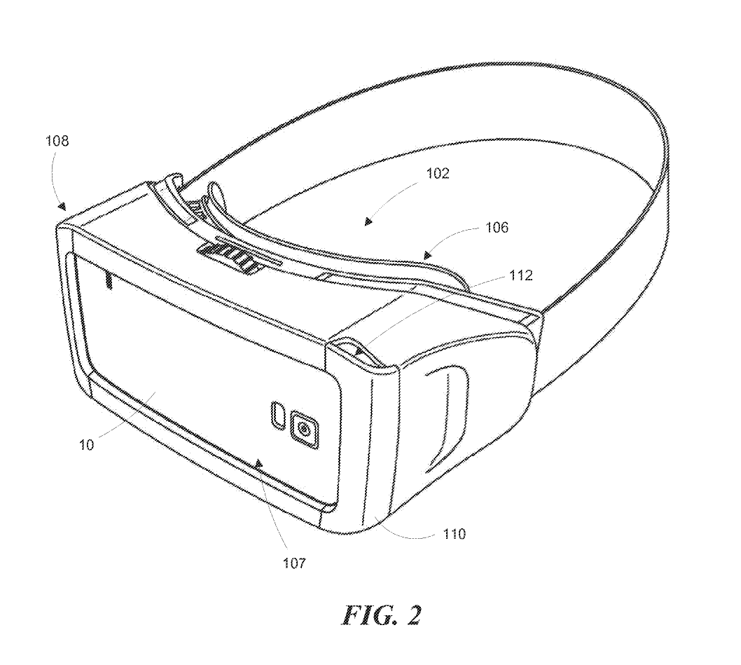

As shown in FIG. 2, the housing body 102 includes a facial interface portion 106 configured to confront the face of a user. The housing body 102 also contains optics, such as conventional optics used in virtual reality head mounted displays. The optics are adjacent to a display receptacle 107 configured to receive a portable display device 10. The housing body 102 includes a frame portion 108 that removably contains the portable display device 10 in the display receptacle 107 adjacent to the optics when the display device 10 is in an installed position. A contoured door 110 is positioned on the housing body 102 adjacent to the frame portion 108 and is operative to move between a closed position and an open position. When the display device 10 is in the installed position within the housing body 102, the door 110 in the closed position (FIG. 2) and the frame portions block the display device 10 from dislodging or otherwise unintentionally moving relative to the optics. The door 110 in the closed position also blocks the display device 10 from inadvertently sliding out of the frame portion 108. In some embodiments, the housing body 102 includes an opening feature 112, such as a cutout portion defining a space into which a user's fingertip can be inserted to facilitate opening the door 110.

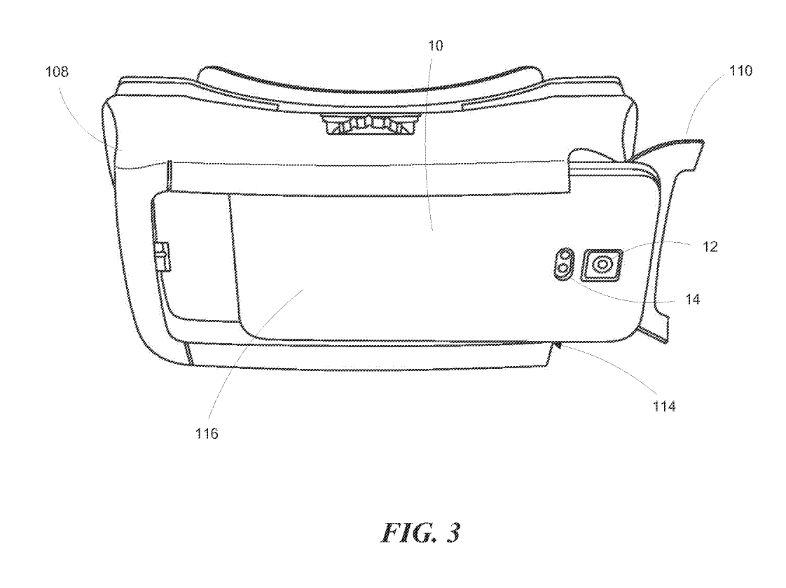

As shown in FIG. 3, when the door 110 is in the open position, access is provided into the display receptacle 107 and the frame portion 108 through an opening 114 on the side portion of the housing body 102. Accordingly, when the door 110 is in the open position, the portable display device 10 can be slid or otherwise moved into display receptacle 107 with the frame portion 108 surrounding the side portions of the display device 10. The door 102 in the open position also allows the display device to be slid or otherwise moved out of the housing body 102. In some embodiments, the frame portion 108 includes an open region 116 that exposes a large portion of the display device 10. In other embodiments, open region 116 can be smaller or eliminated. In some embodiments, open region 116 can generally correspond to an area defined by camera 12 and flash 14.

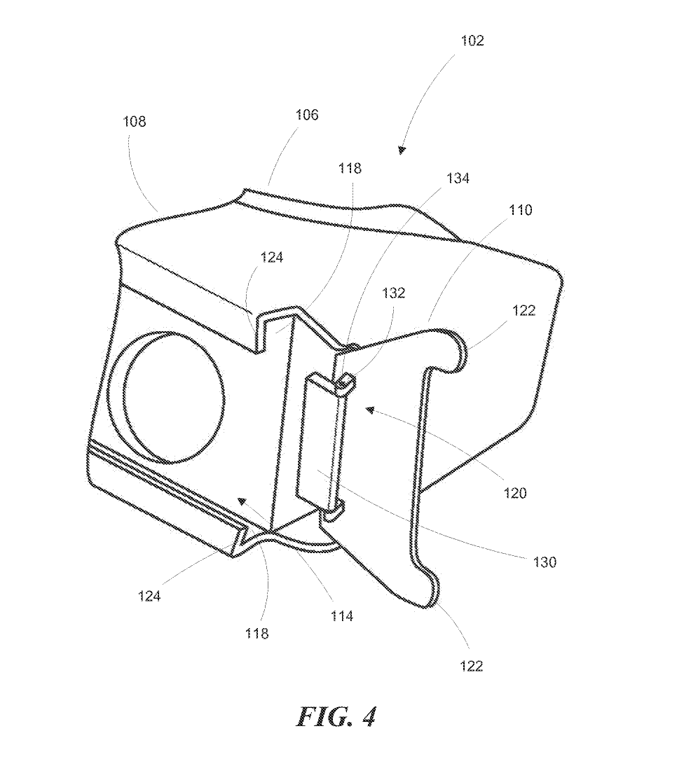

As shown in FIG. 4, the door 110 is positioned adjacent the opening 114. A hinge 120 couples the door 110 to the housing body 102. The hinge 120 includes a door mount 130 attached to the frame portion 108. In some embodiments, the door mount 130 is integrally formed with the frame portion 108. For example, the door mount 130 can be integrally molded with the frame portion 108. The door 110 includes a pair of ears 132 that mate with the door mount 130. In some embodiments, the door 110 is retained on the door mount 130 with a hinge pin 134 extending through the ears 132 and the door mount 130. In some embodiments, the door 110 includes one or more tabs 122 that releasably engage with corresponding one or more latch portions 124 of the frame portion 108 to hold the door 110 in the close position. In some embodiments, frame portion 108 includes surrounding channels 118 that receive the portable display device 10 (not shown). When door 110 is in the closed position, the door 110 encloses the opening 114, thereby completing the surrounding channels 118 to comprise a complete frame. In some embodiments, the door 110 swings away from the frame portion 108 and towards the facial interface portion 106.

### Remarks

The above description and drawings are illustrative and are not to be construed as limiting. Numerous specific details are described to provide a thorough understanding of the disclosure. However, in some instances, well-known details are not described in order to avoid obscuring the description. Further, various modifications may be made without deviating from the scope of the embodiments. Accordingly, the embodiments are not limited except as by the appended claims.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

The terms used in this specification generally have their ordinary meanings in the art, within the context of the disclosure, and in the specific context where each term is used. It will be appreciated that the same thing can be said in more than one way. Consequently, alternative language and synonyms may be used for any one or more of the terms discussed herein, and any special significance is not to be placed upon whether or not a term is elaborated or discussed herein. Synonyms for some terms are provided. A recital of one or more synonyms does not exclude the use of other synonyms. The use of examples anywhere in this specification, including examples of any term discussed herein, is illustrative only and is not intended to further limit the scope and meaning of the disclosure or of any exemplified term. Likewise, the disclosure is not limited to various embodiments given in this specification. Unless otherwise defined, all technical and scientific terms used herein have the same meaning as commonly understood by one of ordinary skill in the art to which this disclosure pertains. In the case of conflict, the present document, including definitions, will control.

What is claimed is:

1. A head mounted display for use with a portable display device, comprising:
a housing body including:
a facial interface portion configured to confront a face of a user, and
a frame portion having an opening configured to removably receive the portable display device; and
a door positioned on the housing body adjacent the opening and operative to move between an open position to allow access to the frame portion and a closed position to retain the portable display device in the frame portion.

2. The head mounted display of claim 1, further comprising a strap assembly coupled to the housing body and adapted to retain the facial interface portion against the face of the user.

3. The head mounted display of claim 1, wherein the door encloses the opening when in the closed position, thereby completing the frame portion.

4. The head mounted display of claim 1, further comprising a hinge coupling the door to the housing body.

5. The head mounted display of claim 1, wherein the door includes a pair of tabs configured to latch against the frame portion.

6. The head mounted display of claim 1, wherein the frame portion includes surrounding channels positioned to receive the portable display device.

7. The head mounted display of claim 1, wherein the housing body includes a finger opening to facilitate opening the door.

8. The head mounted display of claim 1, wherein the door swings toward the facial interface portion when opened.

9. A head mounted display housing for use with a portable display device, comprising:
a housing body including:
a facial interface portion configured to confront a face of a user,
a frame portion having surrounding channels configured to contain the portable display device and an opening configured to receive the portable display device into the surrounding channels, and
a door mount positioned adjacent the opening;
a door coupled to the door mount and operative to move between an open position to allow access to the surrounding channels and a closed position to retain the portable display device in the frame portion; and
a strap assembly coupled to the housing body and adapted to retain the facial interface portion against the face of the user.

10. The head mounted display housing of claim 9, wherein the door encloses the opening when in the closed position, thereby completing the surrounding channels.

11. The head mounted display housing of claim 9, wherein the door includes a pair of tabs configured to latch against the frame portion.

12. The head mounted display housing of claim 9, wherein the housing body includes a finger opening to facilitate opening the door.

13. The head mounted display housing of claim 9, wherein the door swings toward the facial interface portion when opened.

14. The head mounted display housing of claim 9, wherein the door mount comprises a hinge.

15. A head mounted display for use with a portable display device, comprising:
a housing body including:
a facial interface portion configured to confront a face of a user,
a frame portion having surrounding channels configured to contain the portable display device and an opening configured to receive the portable display device into the surrounding channels, and
a door mount positioned adjacent the opening;
a contoured door coupled to the door mount and operative to move between an open position to allow access to the surrounding channels and a closed position to retain the portable display device in the frame portion, wherein the door includes a pair of tabs configured to latch against the frame portion; and
a strap assembly coupled to the housing body and adapted to retain the facial interface portion against the face of the user.

16. The head mounted display of claim 15, wherein the door encloses the opening when in the closed position, thereby completing the surrounding channels.

17. The head mounted display of claim 16, wherein the housing body includes a finger opening to facilitate opening the door.

18. The head mounted display of claim 17, wherein the door swings toward the facial interface portion when opened.

19. The head mounted display of claim 18, wherein the door mount comprises a hinge.
